(19) United States
(12) Patent Application Publication
(10) Pub. No.: US 2006/0257749 A1
(43) Pub. Date: Nov. 16, 2006

(54) METHOD FOR REDUCING CRITICAL DIMENSION

(76) Inventors: Sheng-Yueh Chang, Taipei County (TW); Te-Hung Wu, Tainan County (TW); Kuo-Chun Huang, Tainan City (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/908,513

(22) Filed: May 16, 2005

(51) Int. Cl. G03F 1/00; G03C 5/00

(52) U.S. Cl. 430/5; 430/394

(57) ABSTRACT

A method for reducing critical dimension is provided. An exposure process and a develop process are performed on a photoresist layer. An optical trim exposure process is performed between the exposure process and the development process or before the exposure process. The optical trim expsoure process is performed to expose the photoresit layer by using a fully open mask of which the transmission rate is greater than zero. Because of the performance of the optical trim exposure process, the critical dimension of the photoresist layer can be reduced without substantially changing the characteristics of the photoresist layer.

### BACKGROUND OF THE INVENTION

1. Field of the Invention

The present invention relates to semiconductor process. More particularly, the present invention relates to a method for reducing the critical dimension (CD).

2. Description of Related Art

To satisfy the constant demand for a higher integration of devices, the dimension of the entire circuit device is continually being reduced in each successive technology generation. However, a further scaling-down of a device's dimension is constrained by the existing photolithographic techniques.

Limited by the yellow light process, the photolithographic process can not be improved to achieve a smaller critical dimension. Therefore, the industry has developed a photoresist trimming process, which includes a chemical trim process and a plasma trim process.

The chemical trim process is achieved by submerging the patterned photoresist layer and the entire wafer thereunder in a basic or a neutral chemical solution. A portion of the photoresist layer is removed and the critical dimension is thereby reduced. However, the exact reduction of the critical dimension is difficult to control by this type process, and an over-trimming is easily occurred. In fact, the photoresist layer can be entirely removed. To prevent such a scenario from happening, the shrinkage volume must be carefully controlled. In other words, the reduction of the critical dimension can also be better controlled. Moreover, after the treatment with the chemical solution, the property of the sidewall of the photoresist changes, which in turns affects the etching resistance of the photoresist. In order to ensure the accuracy of the photolithography process, the photoresist layer is first being examined with a scanning electron microscope (SEM) or a similar type of apparatus before proceeding to the next process. However, the etching resistance of the sidewall of the photoresist layer is again affected after being subjected to the scanning with a SEM.

In a plasma trim process, the wafer is exposed to an appropriate plasma etchant. Using ion bombardment, the photoresist layer on the wafer surface is trimmed to reduce the critical dimension. However, due to the nature of the plasma trim process, the trimming of a line-end is not desirable. A predetermined length of the line can not be maintained. Further, to prevent the entire line from being trimmed, the shrinkage volume must also be limited. Additionally, the longer the trimming process, the lower the yield of the lithographic process. Since the properties of the exposed photoresist layer may change after being bombarded by ions, the rework process cannot be continued. Consequently, more time is consumed and a high cost is resulted for re-depositing a photoresist layer.

### SUMMARY OF THE INVENTION

At least one object of the present invention is to provide a method for reducing the critical dimension, wherein the conventional chemical trim process and the plasma trim process can be replaced such that the cycle time for reducing critical dimension is reduced and the process is simplified.

The present invention also provides a method for reducing the critical dimension, wherein alterations of the property of the photoresist layer due to the trimming process is prevented to facilitate the subsequent process.

The present invention provides a method for reducing the critical dimension, which includes performing an exposure process and a development process on a photoresist layer, wherein an optical trim exposure process (OTP) is conducted between the exposure process and the development process. The optical trim exposure process includes performing an exposure on the photoresist layer using a fully open mask, wherein the transmission rate of a fully open mask is greater than 0.

According to one embodiment of the present invention, the fully open mask includes an alternating phase shift mask (alt-PSM) or a half-tone mask.

According to one embodiment of the invention, between the optical trim exposure process and the development process, a post exposure baking process is performed.

The present invention provides another method for reducing the critical dimension, in which an exposure process and a development process are performed on the photoresist layer, wherein an optical trim exposure process is performed before the standard exposure process, and the optical trim exposure process is conducted using a fully open mask having a transmission rate greater than 0.

According to one embodiment of the present invention, the fully open mask includes an alternating phase shift mask (alt-PSM) or a half-tone mask.

According to one embodiment of the invention, between the optical trim exposure process and the development process, a post exposure baking process is performed.

According to one embodiment of the present invention for reducing the critical dimension, the critical dimension of the photoresist layer can be reduced to within a range of about 4 nm to 100 nm.

The optical trim exposure process of the present invention can replace the conventional chemical trim process or the plasma trim process to reduce the cycle time and to simply the process. Further, the present invention is not limited by shrinkage volume, and the critical dimension can be accurately reduced. Further, any alteration to the properties of the photoresist layer due to the trimming process can be obviated and the subsequent process can be facilitated.

The above is a brief description of some deficiencies in the prior art and advantages of the present invention. Other features, advantages and embodiments of the invention will be apparent to those skilled in the art from the following description, accompanying drawings and appended claims.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a flow chart of a fabrication process for reducing the critical dimension according to one embodiment of the invention.

FIG. 2A to 2D are schematic, cross sectional views showing the steps of a method for reducing the critical dimension according to one embodiment of the invention.

FIG. 3 is a flow chart of a fabrication process for reducing the critical dimension according to another embodiment of the invention.

### DESCRIPTION OF THE PREFERRED EMBODIMENTS

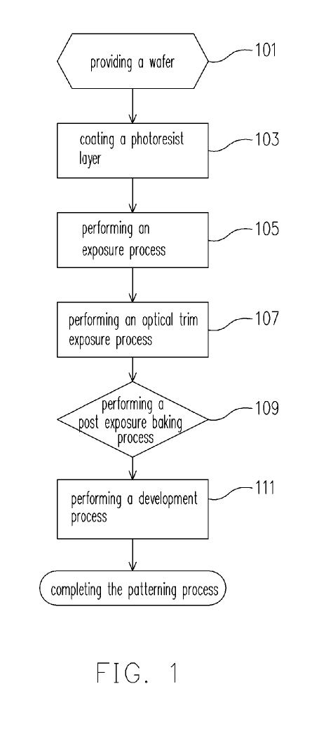

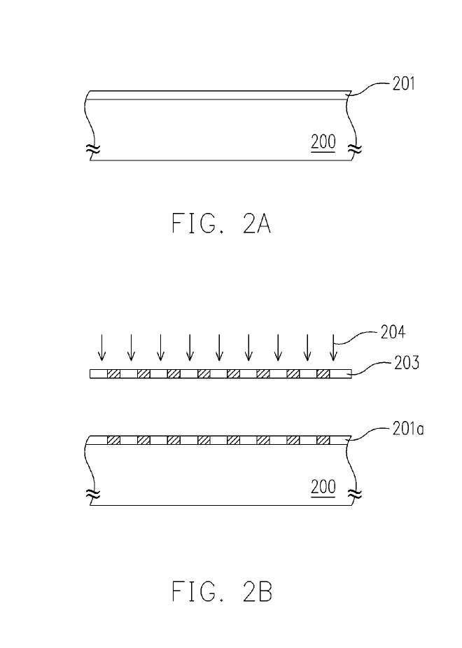

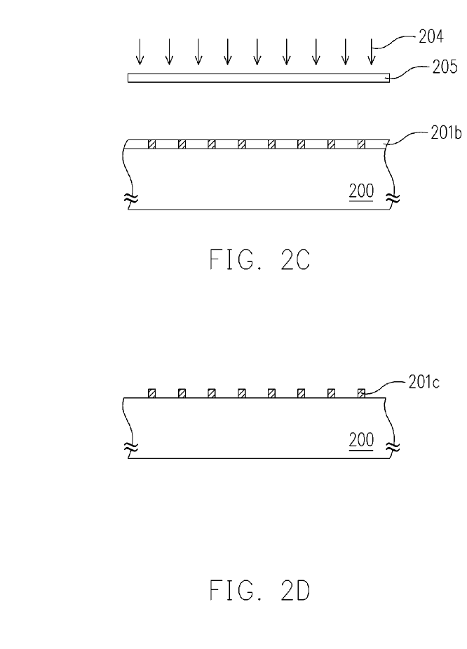

FIG. 1 is a flow chart of a fabrication process for reducing the critical dimension according to one embodiment of the invention. FIG. 2A to 2D are schematic, cross sectional views showing the steps of a method for reducing the critical dimension according to one embodiment of the invention.

Referring to both FIGS. 1 and 2A, a wafer 200 (step 101) is provided. The wafer 200 is already formed with, for examples, transistors, memory or other semiconductor devices thereon or the wafer 200 does not have any devices formed thereon. The surface of the wafer 200 can include a dielectric layer, a conductive layer, a protective layer or any film layer that requires an etching process or a doping process, etc. A photoresist layer 201 (step 103) is then coated on the wafer 200, wherein the coating method includes, but not limited to, spin coating. The photoresist layer 201 is, for example, a positive photoresist.

Thereafter, as shown in FIG. 2B, using a photomask 203, an exposure process (step 105) is performed on the photoresist layer 201 to form a photoresist layer 201 a with a latent image. Since after an exposure process and before a development process, the changes on the photoresist layer 201 cannot be visually observed. A photoresist layer 201, after it is being exposed but before being developed, is known as a photoresist layer 201 a with a latent image. The exposure light source 204 used in the exposure process includes, for example, krypton fluoride laser, argon fluoride or other types of deep ultraviolet light source.

Continuing to FIG. 2C, after the exposure process, an optic trim exposure process (step 107) is performed, wherein the optical trim exposure process employs a fully open mask 205. A fully open mask 205 refers to a mask with no pattern thereon and the transmission rate of a fully open mask 205 is greater than 0. The fully open mask 205 includes an alternate phase shift mask or a halftone mask.

In one embodiment, after the optical trim exposure process, a post exposure baking process (step 109) is performed. The post exposure baking process includes baking with a hot plate at about 110° C. to about 130° C. for about 10 seconds to 2 minutes.

Referring to FIG. 2D, a development process (step 111) is conducted to develop the latent image of the photoresist layer 201b to form a patterned photoresist layer 201c. The critical dimension of the patterned photoresist layer 201c is about 4 nm to about 100 nm.

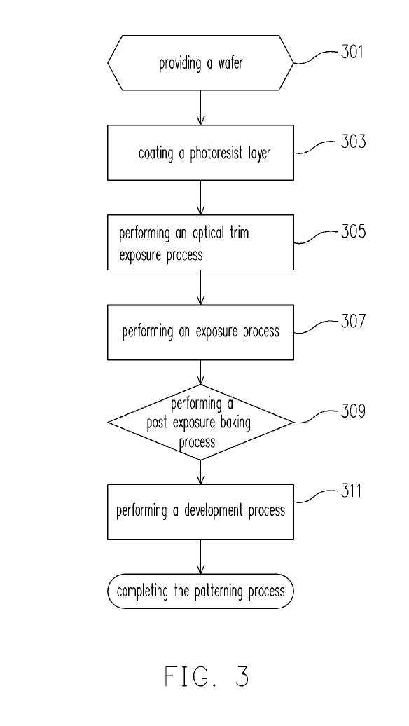

Also, the aforementioned optical trim exposure process can also be executed before the exposure process as shown in FIG. 3. FIG. 3 is a flow chart of a fabrication process for reducing the critical dimension according to another embodiment of the invention.

Referring to FIG. 3, a wafer (step 301) is provided. The wafer 200 is already formed with, for examples, transistors, memory or other semiconductor devices thereon or the wafer 200 not yet has any devices formed thereon. The surface of the wafer 200 can include a dielectric layer, a conductive layer, a protective layer or any film layer that requires an etching process or a doping process, etc. A photoresist layer 201 (step 103) is then coated on the wafer 200, wherein the coating method includes, but not limited to, spin coating. The photoresist layer 201 is, for example, a positive photoresist.

Thereafter, an optic trim exposure process (step 305) is performed to obtain a photoresist layer with a latent image, wherein the optical trim exposure process employs a fully open mask 205,and the transmission rate of the fully open mask 205 is greater than 0. The fully open mask 205 includes an alternate phase shift mask or a halftone mask, for example.

After the optical trim exposure process, an exposure process (step 307) is performed on the photoresist layer using a photomask to obtain another photoresist layer with a latent image. The exposure light source 204 used in the exposure process includes, for example, krypton fluoride laser, argon fluoride or other deep ultraviolet light source.

In one embodiment of the invention, after the exposure process, a post-exposure baking process (step 309) is performed. This post-exposure baking process includes baking with a hot plate at about 110° C. to about 130° C. for about 10 seconds to 2 minutes.

Thereafter, a development process (step 311) is performed to develop the latent image of the photoresist layer to form a patterned photoresist layer. After the completion of step 311 as shown in FIG. 2D, the critical dimension of the patterned photoresist layer is about 4 nm to about 100 nm, wherein the development process is accomplished by an acid-base neutralizing reaction.

Accordingly, the present invention employs an optical trim exposure process to replace the conventional chemical trim or plasma trim process in order to be more time effective and to simplify the process.

Moreover, in accordance of the present invention, the problems of negatively impacting the properties of photoresist layer as in other trimming processes can be obviated to facilitate the photoresist rework process. The etch resistance of the photoresist sidewall is also retained to ensure an accurate transferring of the patterns.

The foregoing description of the preferred embodiment of the present invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to best explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

What is claimed is:

1. A method for reducing a critical dimension, wherein an exposure process and a development process are performed on a photoresist layer, the method comprising:
performing an optical trim exposure process between the exposure process and the development process, wherein the optical trim exposure process employs a fully open mask with a transmission rate greater than 0.

2. The method of claim 1, wherein the fully open mask comprises a half-tone mask.

3. The method of claim 1, wherein the fully open mask comprises a phase shift mask.

4. The method of claim 3, wherein the phase shift mask (PSM) comprises a chromeless mask (CLM), an alternating phase shift mask (alt-PSM) or an attenuated phase shift mask (att-PSM).

5. The method of claim 1 further comprising a post exposure baking process between the optical trim exposure process and the development process.

6. The method of claim 1, wherein the critical dimension of the photoresist layer is about 4 nm to about 100 nm.

7. A method for reducing a critical dimension, wherein an exposure process and a development process are performed on a photoresist layer, the method comprising:
performing an optical trim exposure process on the photoresist layer before the exposure process, wherein the optical trim exposure process employs a fully open mask of which a transmission rate is greater than 0.

8. The method of claim 7, wherein the fully open mask comprises a half-tone mask.

9. The method of claim 7, wherein the fully open mask comprises a phase shift mask.

10. The method of claim 9, wherein the phase shift mask (PSM) comprises a chromeless mask (CLM), an alternating phase shift mask (alt-PSM) or an attenuated phase shift mask (att-PSM).

11. The method of claim 7 further comprising a post exposure baking process between the optical trim exposure process and the development process.

12. The method of claim 7, wherein the critical dimension of the photoresist layer is about 4 nm to about 100 nm.
